(19) United States
(12) Patent Application Publication
(10) Pub. No.: US 2016/0013312 A1
(43) Pub. Date: Jan. 14, 2016

(54) SEMICONDUCTOR DEVICE AND MANUFACTURING METHOD THEREFOR

(71) Applicant: PS4 LUXCO S.A.R.L, Luxembourg (LU)

(72) Inventor: Hiroyuki Fujimoto, Tokyo (JP)

(21) Appl. No.: 14/771,892

(22) PCT Filed: Mar. 3, 2014
(86) PCT No.: PCT/JP2014/055314

§ 371 Date: Sep. 1, 2015

(30) Foreign Application Priority Data
Mar. 5, 2013 (JP) 2013-043019

(51) Int. Cl. H01L 29/78; H01L 29/45; H01L 29/417; H01L 21/225; H01L 29/08; H01L 29/10; H01L 27/108; H01L 21/324; H01L 29/66; H01L 29/06

(52) U.S. Cl. CPC H01L 29/7827; H01L 29/66666; H01L 29/456; H01L 29/41741; H01L 29/0642; H01L 29/0847; H01L 29/1037; H01L 27/10873; H01L 27/10888; H01L 27/10805; H01L 21/324; H01L 21/2251

(57) ABSTRACT

One semiconductor device includes an element-isolation region formed on a semiconductor substrate, an active region surrounded by said element-isolation region, a semiconductor pillar in the active region and protruding from the surface of the substrate, a gate electrode on a side surface of the pillar, with a gate-insulating film interposed there between, and extending in a first direction, a pillar-top diffusion layer in the top-end section of the pillar, a pillar-bottom diffusion layer in the bottom-end section of the pillar, a channel section between the pillar-top diffusion layer and the pillar-bottom diffusion layer, a silicide layer beneath the pillar-bottom diffusion layer and extending in a second direction perpendicular to the first direction, a contact plug to contact the silicide layer in the bottom-end section, and top-layer wiring to contact the contact plug in the top-end section. The contact plug is connected to the silicide layer through the pillar-bottom diffusion layer.

### FIELD

The present invention relates to a semiconductor device and a manufacturing method therefor.

### BACKGROUND

Recently, a vertical transistor has been provided as a technique for miniaturizing a transistor. A vertical transistor is a transistor that uses a semiconductor pillar (core) extending vertically to the principal surface of a semiconductor substrate as a channel. Specifically, a vertical transistor has a semiconductor pillar disposed so as to rise from a semiconductor substrate, and a gate electrode disposed around the semiconductor pillar with a gate insulating film in between. A drain region and a drain electrode are disposed beneath the semiconductor pillar, and a source region and a source electrode are disposed above the semiconductor pillar.

This vertical transistor occupies less area on a plane compared to a conventional transistor having a channel arranged parallel to the principal surface of the core (the surface on which the transistor is formed), and the area occupied by the transistor on the plane does not increase even if the channel length (gate length) is lengthened. Therefore, a short-channel effect can be minimized even without enlarging the area occupied by the transistor on the plane. The channel can also be depleted completely, which has the advantage of obtaining a good S value (subthreshold swing value) and a large drain current.

Japanese Unexamined Patent Publication No. 2007-329480 (Patent Document 1), for example, has disclosed a memory cell structure of a dynamic random access memory (DRAM) using such a vertical transistor.

### PATENT DOCUMENT

### Patent Document 1: Japanese Unexamined Patent Publication No. 2007-329480

### OUTLINE OF THE INVENTION

### Problems that the Invention is to Solve

The Patent Document 1 has described a configuration in FIG. 1 in which a channel structure 11 is arranged on a pedestal comprising a semiconductor substrate 21 interposed between two bit line grooves. With this configuration, two bit lines 13 are formed on either side of the pedestal. A drain region 81a located on the top surface of the pedestal beneath the channel structure is interposed between the two bit lines 13, and is arranged connected to the bit lines.

With this configuration, connections from a top-layer wiring (not shown) to the bit lines 13 are made through the drain region 81a. The drain diffusion layer 81a comprises an impurity diffusion layer formed on a silicon substrate, which increases the connection resistance between the top-layer wiring and the bit lines, and causes the problem of delaying the operation of the DRAM.

The present invention provides a semiconductor device capable of stabilizing operation by avoiding an increase in the connection resistance between a top-layer wiring and a bit line; and a manufacturing method therefor.

### Means of Solving the Problems

A semiconductor device according to an aspect of the present invention is characterized in having an element-isolation region formed on a semiconductor substrate;

an active region surrounded by the element-isolation region;

a semiconductor pillar disposed in the active region so as to protrude from the surface of the semiconductor substrate;

a gate electrode disposed on a side surface of the semiconductor pillar, with a gate insulating film interposed in between, so as to extend in a first direction;

a pillar-top diffusion layer disposed on a top-end section of the semiconductor pillar;

a pillar-bottom diffusion layer disposed on a bottom-end section of the semiconductor pillar;

a channel section disposed between the pillar-top diffusion layer and the pillar-bottom diffusion layer;

a silicide layer disposed beneath the pillar-bottom diffusion layer so as to extend in a second direction perpendicular to the first direction;

a contact plug disposed so as to contact the silicide layer at a bottom-end section; and

a top-layer wiring disposed so as to contact the contact plug at a top-end section; and

the contact plug passing through the pillar-bottom diffusion layer to connect to the silicide layer.

A method of manufacturing a semiconductor device according to an aspect of the present invention is characterized in that an element-isolation region is formed on a semiconductor substrate;

an active region is formed surrounded by the element-isolation region;

a pillar-shaped semiconductor pillar is formed in the active region so as to protrude from the surface of the semiconductor substrate;

a gate electrode is formed on a side surface of the semiconductor pillar, with a gate insulating film interposed in between, so as to extend in a first direction;

a pillar-top diffusion layer is formed on a top-end section of the semiconductor pillar;

a pillar-bottom diffusion layer is formed on a bottom-end section of the semiconductor pillar;

a channel section is formed between the pillar-top diffusion layer and the pillar-bottom diffusion layer;

a silicide layer is formed beneath the pillar-bottom diffusion layer so as to extend in a second direction perpendicular to the first direction;

a contact plug is formed so as to contact the silicide layer at a bottom-end section;

a top-layer wiring is formed so as to contact the contact plug at a top-end section; and

the contact plug is passed through the pillar-bottom diffusion layer to connect to the silicide layer.

### Effects of the Invention

The present invention can stabilize the operation of a semiconductor device by avoiding an increase in the connection resistance between a top-layer wiring and a bit line.

### BRIEF EXPLANATION OF THE DRAWINGS

FIG. 1A is a schematic view showing the structure of the semiconductor device 100 according to the first embodiment of the present invention, and is a plan view of the semiconductor device 100;

FIG. 1B is a schematic view showing the structure of the semiconductor device 100 according to the first embodiment of the present invention, and is a sectional view at A-A′ in FIG. 1A;

FIG. 1C is a schematic view showing the structure of the semiconductor device 100 according to the first embodiment of the present invention, and is a sectional view at B-B′ in FIG. 1A;

FIG. 1D is a schematic view showing the structure of the semiconductor device 100 according to the first embodiment of the present invention, and is a sectional view at C-C′ in FIG. 1A;

FIG. 1E is a schematic view showing the structure of the semiconductor device 100 according to the first embodiment of the present invention, and is a sectional view at D-D′ in FIG. 1A;

FIG. 1F is a schematic view showing the structure of the semiconductor device 100 according to the first embodiment of the present invention, and is a sectional view at E-E′ in FIG. 1A;

FIG. 2D is a sectional view showing the semiconductor device 200 according to the second embodiment of the present invention;

FIG. 2F is a sectional view showing the semiconductor device 200 according to the second embodiment of the present invention;

FIG. 3D is a sectional view showing the semiconductor device 300 according to the third embodiment of the present invention;

FIG. 3F is a sectional view showing the semiconductor device 300 according to the third embodiment of the present invention;

FIG. 4A is a process drawing illustrating the method of manufacturing the semiconductor device 100 according to the first embodiment of the present invention;

FIG. 4B is a process drawing illustrating the method of manufacturing the semiconductor device 100 according to the first embodiment of the present invention;

FIG. 5A is a process drawing illustrating the method of manufacturing the semiconductor device 100 according to the first embodiment of the present invention;

FIG. 5B is a process drawing illustrating the method of manufacturing the semiconductor device 100 according to the first embodiment of the present invention;

FIG. 6B is a process drawing illustrating the method of manufacturing the semiconductor device 100 according to the first embodiment of the present invention;

FIG. 7B is a process drawing illustrating the method of manufacturing the semiconductor device 100 according to the first embodiment of the present invention;

FIG. 8A is a process drawing illustrating the method of manufacturing the semiconductor device 100 according to the first embodiment of the present invention;

FIG. 8B is a process drawing illustrating the method of manufacturing the semiconductor device 100 according to the first embodiment of the present invention;

FIG. 8C is a process drawing illustrating the method of manufacturing the semiconductor device 100 according to the first embodiment of the present invention;

FIG. 8D is a process drawing illustrating the method of manufacturing the semiconductor device 100 according to the first embodiment of the present invention;

FIG. 8E is a process drawing illustrating the method of manufacturing the semiconductor device 100 according to the first embodiment of the present invention;

FIG. 8G is a process drawing illustrating the method of manufacturing the semiconductor device 100 according to the first embodiment of the present invention;

FIG. 9A is a process drawing illustrating the method of manufacturing the semiconductor device 100 according to the first embodiment of the present invention;

FIG. 9B is a process drawing illustrating the method of manufacturing the semiconductor device 100 according to the first embodiment of the present invention;

FIG. 9C is a process drawing illustrating the method of manufacturing the semiconductor device 100 according to the first embodiment of the present invention;

FIG. 10A is a process drawing illustrating the method of manufacturing the semiconductor device 100 according to the first embodiment of the present invention;

FIG. 10B is a process drawing illustrating the method of manufacturing the semiconductor device 100 according to the first embodiment of the present;

FIG. 10C is a process drawing illustrating the method of manufacturing the semiconductor device 100 according to the first embodiment of the present invention;

FIG. 11A is a process drawing illustrating the method of manufacturing the semiconductor device 100 according to the first embodiment of the present invention;

FIG. 11B is a process drawing illustrating the method of manufacturing the semiconductor device 100 according to the first embodiment of the present invention;

FIG. 11C is a process drawing illustrating the method of manufacturing the semiconductor device 100 according to the first embodiment of the present invention;

FIG. 11D is a process drawing illustrating the method of manufacturing the semiconductor device 100 according to the first embodiment of the present invention; and

FIG. 11E is a process drawing illustrating the method of manufacturing the semiconductor device 100 according to the first embodiment of the present invention.

### EMBODIMENTS OF THE INVENTION

Preferred embodiments of the present invention will be described in detail hereinafter with reference to the annexed drawings.

### First Embodiment

A first embodiment of the present invention will be described is detail hereinafter with reference to the annexed drawings.

The scale, numbers, and the like of the structures in the following drawings differ from the actual structures to facilitate understanding each configuration. An X-Y-Z coordinate system is established to help describe the arrangement of each configuration. In this coordinate system, the Z direction is the direction perpendicular to the principal surface of the silicon substrate, the X direction is a direction orthogonal to the Z direction, and the Y direction is a direction orthogonal to the X direction in a horizontal plane with the principal surface of the silicon substrate.

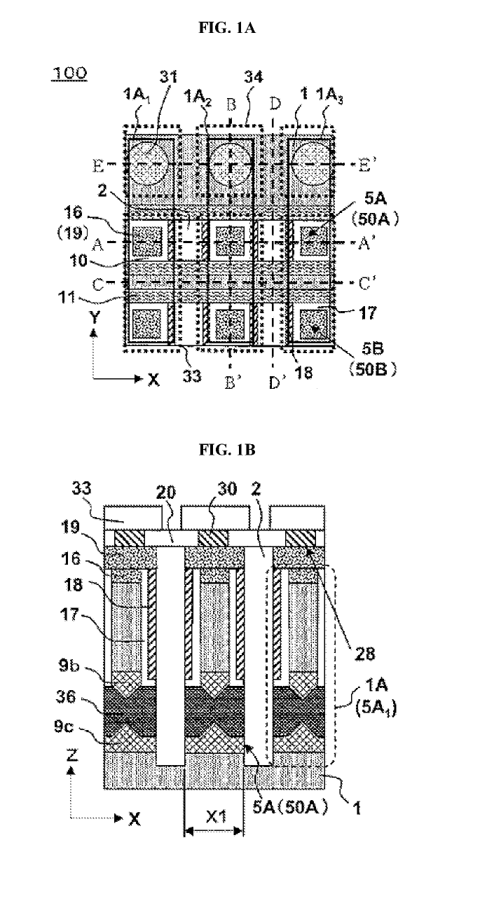

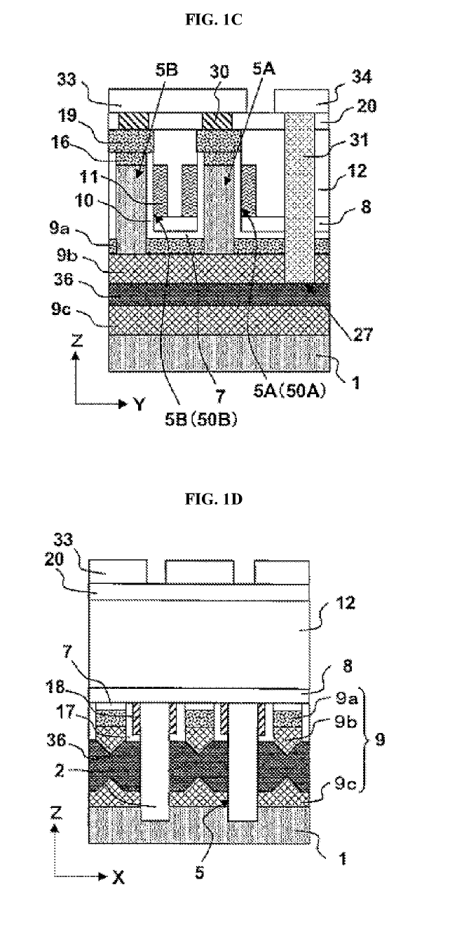

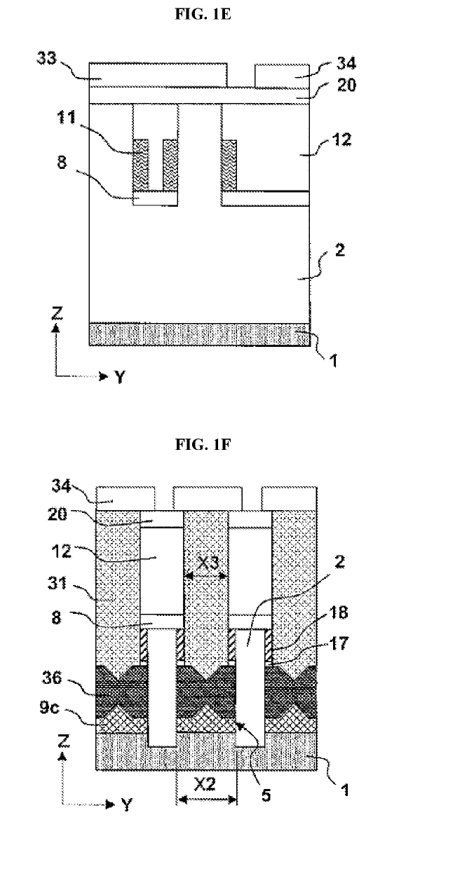

FIG. 1 is a schematic view showing the structure of the semiconductor device 100 according to the first embodiment of the present invention. FIG. 1A is a pan view of the semiconductor device 100, FIG. 1B is a sectional view at A-A′ in FIG. 1A, FIG. 1C is a sectional view at B-B′ in FIG. 1A, FIG. 1D is a sectional view at C-C′ in FIG. 1A, FIG. 1E is a sectional view at D-D′ in FIG. 1A, and FIG. 1F is a sectional view at E-E′ in FIG. 1A. In FIG. 1A, however, the wirings located on the interlayer insulating film, the silicon plug, and the contact plug are transparent and their contours are delineated by dotted lines to show the arrangement of the components more clearly.

First, as shown in FIG. 1A, the semiconductor device 100 according to the first embodiment has a shallow trench isolation (STI) 2 as an element-isolation region, and three active regions 1A (dashed-line regions: 1A₁-1A₃) comprising semiconductor substrates surrounded by the STI 2 on a semiconductor substrate comprising a single silicon crystal. Two transistors, a first unit transistor 50A and a second unit transistor 50B comprising vertical transistors disposed so as to protrude from the surface of the semiconductor substrate, are arranged in one active region 1A so as to form a convex shape. Hereafter, the first unit transistor 50A and the second unit transistor 50B will be collectively called the unit transistors 50.

An impurity diffusion layer is disposed in the active region 1A located beneath the unit transistors 50, and constitutes a pillar-bottom diffusion layer shared by the vertical transistors. Metal contact plugs 31, each of which is shared by the vertical transistors of that active region, are arranged at the edges of the active regions 1A, and metal wirings 34 are arranged on the top surfaces of the metal contact plugs 31. Metal contact plugs 30 are arranged above the vertical transistors, and are connected to each other to form a structure by a wiring 33 arranged abutting the top surfaces of the metal contact plugs 30.

Therefore, a structure is formed in which the vertical transistors in each of the active regions are connected below by sharing a pillar-bottom diffusion layer, and are connected above by arranging the wiring 33. That is, the semiconductor device 100 comprises one vertical transistor in which two vertical transistors are connected in parallel. Each of the unit transistors 50 is arranged in a peripheral region of one side surface of the metal contact plug 31 in the Y direction. The silicon pillars 5 comprising the channels of the unit transistors 50 are configured so as to form a rectangle in which the width in the X direction is the same as the width in the Y direction perpendicular to the X direction. The width in this case is 50 nm. The planar shape of the silicon pillars 5 is not limited to a rectangle, and may be a circle. In the case of a circle, the diameter is 50 nm.

Thus, the silicon pillars 5 comprise the channels of the unit transistors 50. Specifically, the first silicon pillar 5A corresponds to the first unit transistor 50A, and the second silicon pillar 5B corresponds to the second unit transistor 50B. The two unit transistors 50 are arranged so as to form a linear shape in the Y direction in plan view. A silicon plug 19, a metal contact plug 30, and a metal wiring 33 are arranged just above the unit transistors 50. Each of the unit transistors 50 is arranged overlapping the silicon plug 19 and the metal contact plug 30 within the same region in plan view.

The metal wiring 33 is arranged extending in one of a Y direction so as to form a linear shape following the arrangements of the two unit transistors 50. The metal wiring 33 is formed above the silicon pillars with the metal contact plug 30 in between, is connected to pillar-top diffusion layers 16 constituting the unit transistors, and forms a power supply wiring to the unit transistors. Thus, the two unit transistors 50 are connected in parallel by the metal wiring 33, and comprise one parallel transistor. Gate electrodes 11 forming a double-gate structure are disposed through gate insulating films 10 on the two side surfaces of the silicon pillars 5 in the Y direction. The gate electrodes 11, extending in the X direction, are connected to each other at the sidewalls between adjacent silicon pillars in the X direction, and are shared by a plurality of silicon pillars 5.

Next, the structure of the semiconductor device 100 will be described in greater detail with reference to the sectional views in FIGS. 1B to 1F.

The STI 2 is disposed on a silicon substrate 1. Two silicon pillars 5 of the first silicon pillar 5A and the second silicon pillar 5B comprising semiconductor cores (semiconductor pillars) are erected in the active regions 1A comprising the silicon substrate 1 surrounded by the STI 2. The silicon pillars 5 are pillar-shaped semiconductors constituting the channels of the corresponding unit transistors 50. Therefore, the unit transistors 50 are vertical transistors. The two silicon pillars 5 are arranged all at the same height in the active regions 1A divided by the STI 2. The thickness of the silicon pillars (the size of cross sections cut by a plane parallel to the surface of the silicon substrate 1) is a thickness that allows complete depletion.

The unit transistors 50 have impurity diffusion layers in a top-end section and a bottom-end section of the silicon pillars 5. The pillar-top diffusion layer 16 arranged in a top-end section of the silicon pillar 5 is one of a source or a drain, and the pillar-bottom diffusion layer 9 arranged in a bottom-end section of the silicon pillar 5 is the other of a source or a drain. The central section of the silicon pillars between the pillar-top diffusion layer 16 and the pillar-bottom diffusion layer 9 constitutes a channel.

Described in greater detail, the pillar-bottom diffusion layer 9 has a three-layer structure in the Z direction, made up of a pillar-bottom diffusion layer 9a comprising the uppermost layer, a pillar-bottom diffusion layer 9b comprising an intermediate layer, and a pillar-bottom diffusion layer 9c comprising the lowermost layer. In this case, the uppermost pillar-bottom diffusion layer 9a functions as the other of a source or a drain, and the other pillar-bottom diffusion layers function as a power supply wiring to the pillar-bottom diffusion layer 9a.

One silicide layer 36 is disposed between the pillar-bottom diffusion layer 9b and the pillar-bottom diffusion layer 9c, and extends in the Y direction in the same manner as the active regions 1A in plan view. The pillar-bottom diffusion layers 9a and 9b are arranged in a central section of the silicon pillars 5 in the X direction, and the silicide layer 36 and the pillar-bottom diffusion layer 9c are arranged connecting from one edge to the other edge of the silicon pillars 5 in the X direction. The width X1 in the X direction of the silicon pillars 5 constituting the unit transistors 50 is the same (X1=X2) as the width X2 in the X direction of the silicon pillars 5 provided with the metal contact plugs 31. The width X3 in the X direction of the metal contact plugs 31 is less than or equal to (X3≦X2) the width X2 in the X direction of the silicon pillars 5 provided with the metal contact plugs 31.

An insulating film 8 is disposed on the top surface of the active regions 1A (silicon substrate 1) on the perimeters of the silicon pillars 5. The insulating film 8 covers the perimeters of the silicon pillars 5, and extends to the STI 2. The pillar-bottom diffusion layer 9 is arranged beneath the insulating film 8 so as to overlap the insulating film 8, and the pillar-bottom diffusion layer 9 and a gate electrode 11 are electrically insulated from each other by the insulating film 8. The pillar-bottom diffusion layer 9 is electrically connected to two silicon pillars, and constitutes a bottom diffusion layer shared by the two unit transistors of the first unit transistor 50A and the second unit transistor 50B.

The silicide layer 36, which contacts the pillar-bottom diffusion layer 9b and the pillar-bottom diffusion layer 9c at the edges in the Z direction, has the same function as the bottom diffusion layer 9b. The STI 2 is disposed in a deeper location than the pillar-bottom diffusion layer 9c, and prevents the pillar-bottom diffusion layer 9 being conductive at the two adjacent active regions on either side of the STI 2. A gate insulating film 10 is arranged on a side surface of the silicon pillar 5 in the Y direction.

The gate electrode 11 is arranged on a side surface of the silicon pillar 5 in the Y direction with the gate insulating film 10 in between. The gate insulating film 10 is connected to an insulating film 7 covering the peripheral region of the silicon pillar 5, and the insulating film 8 arranged on the top surface of the insulating film 7. The insulating film 7 is integrated with the gate insulating film 10, but does not function as a gate insulating film, and therefore is called an “insulating film” 7. The channel of the silicon pillar 5, the pillar-top diffusion layer 16, and the pillar-bottom diffusion layer 9 are electrically insulated from the gate electrode 11 by the gate insulating film 10, the insulating film 7, and the insulating film 8.

Thus, the unit transistors 50 comprise the pillar-bottom diffusion layer 9, the pillar-top diffusion layer 16, the gate insulating film 10, and the gate electrode 11. A first interlayer insulating film 12 is disposed covering the gate electrode 11 and the insulating film 8, and a second interlayer insulating film 20 is disposed covering the first interlayer insulating film 12. The metal wiring 33 is arranged on the top surface of the second interlayer insulating film 20, and the metal contact plug 30 disposed inside a contact hole 28 with the second interlayer insulating film 20 in between, is connected to the pillar-top diffusion layer 16 of each silicon pillar through the silicon plug 19 surrounded by the first interlayer insulating film 12 and the STI 2. The silicon plug 19 is formed by injecting (diffusing) an impurity such as arsenic in silicon, and functions as one of a source or a drain in the unit transistors 50 together with the pillar-top diffusion layer 16.

A sidewall film 18 and an insulating film 17 are arranged on a side surface of the silicon pillar in the X direction. A metal wiring 34 is arranged on the top surface of the metal contact plug 31, and is connected to the silicide layer 36 by the metal contact plug (conductive plug) 31 disposed inside a contact hole 27 with the second interlayer insulating film 20 in between, the first interlayer insulating film 12, the pillar-bottom diffusion layer 9a, and the pillar-bottom diffusion layer 9b. Described in greater detail, the metal wiring 34 is connected to the pillar-bottom diffusion layer 9 constituting the unit transistors through the metal contact plug 31 and the silicide layer 36, and forms a power supply wiring to the pillar-bottom diffusion layer 9. The bottom of the metal contact plug 31 abuts the top surface of the silicide layer 36.

Thus, the semiconductor device 100 according to the first embodiment has first and second unit transistors (50A and 50B) arranged so that the centers are located on the same line in the Y direction, a pillar-bottom diffusion layer 9 which is erected in one active region 1A shared by the first and second unit transistors and comprises one of a source or a drain, and a silicide layer 36 arranged beneath the pillar-bottom diffusion layer 9a; and is configured so that the metal contact plug 31 for supplying power to the semiconductor device 100 passes through the pillar-bottom diffusion layer 9a to connect to the silicide layer 36.

With this configuration, power can be supplied from the metal contact plug 31 to the pillar-bottom diffusion layer 9a through a silicide layer 36 having low connection resistance. Therefore, this can avoid the problem of destabilizing the characteristics of the semiconductor device 100 due to insufficient power supply caused by great connection resistance, as in the conventional technique of supplying power directly to the pillar-bottom diffusion layer 9a.

Although the silicide layer 36 was arranged connected to the silicon pillar 5 in the X direction and the metal contact plug 31 was arranged on the top surface of the silicide layer 36 in FIG. 1, the arrangement of the silicide layer 36 and the configuration of the connection between the silicide layer 36 and the metal contact plug 31 may be modified in various ways, which will be described in detail hereafter. This description will leave out aspects shared with the first embodiment, and describe only the differences.

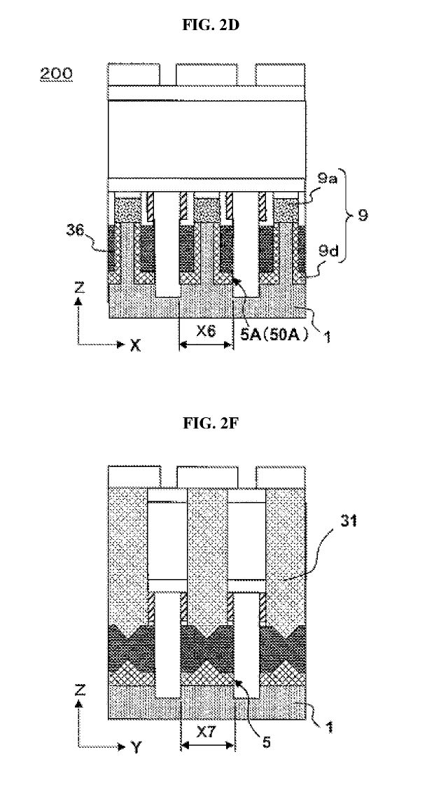

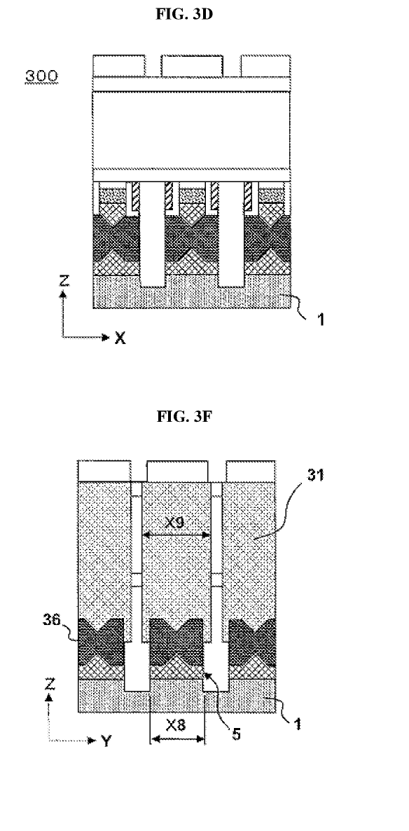

FIGS. 2D and 2F and FIGS. 3D and 3F are sectional views of semiconductor devices having different configurations from the first embodiment, where FIGS. 2 and 3 show sectional views of the same locations as FIGS. 1D and 1F for comparison with the configuration of the first embodiment.

### Second Embodiment

First, the arrangement of the silicide layer 36 will be described with reference to the sectional views in FIGS. 2D and 2F showing a semiconductor device 200 according to a second embodiment. The configuration of the connection between the silicide layer 36 and the metal contact plug 31 is the same as the first embodiment.

The pillar-bottom diffusion layer 9 comprises a pillar-bottom diffusion layer 9a arranged in a central section of the silicon pillars 5 in the X direction, and a pillar-bottom diffusion layer 9d arranged at the edges of the silicon pillar 5 in the X direction. The silicide layers 36 are arranged at the edges of the silicon pillars 5 in the X direction, and extend in the Y direction in the same manner as the active regions 1A in plan view.

That is, where one silicide layer 36 was arranged in one active region 1A in the semiconductor device 100, two silicide layers are arranged in the semiconductor device 200. The edges of the silicide layers 36 inside the silicon pillars 5 are covered by the pillar-bottom diffusion layer 9d. The width X6 in the X direction of the silicon pillars 5 constituting the unit transistors 50 is greater than (X6>X7) the width X7 in the X direction of the silicon pillar 5 provided with the metal contact plug 31. Making X6>X7 in this way allows two silicide layers to be arranged.

### Third Embodiment

Next, a configuration of the connection between the silicide layer 36 and the metal contact plug 31 will be described with reference to FIGS. 3D and 3F showing a semiconductor device 300 according to a third embodiment. The arrangement of the silicide layer 36 in this case is the same as the first embodiment.

The bottom of the metal contact plug 31 is arranged so as to abut the top surface and at least a section of a side surface of the silicide layer 36 in the X direction of the silicon pillars 5. The width X9 in the X direction of the metal contact plug 31 is greater than (X9>X8) the width X8 in the X direction of the silicon pillar 5 provided with the metal contact plug 31. Making X9>X8 in this way allows the bottom of the metal contact plug 31 to connect to a side surface of the silicide layer 36.

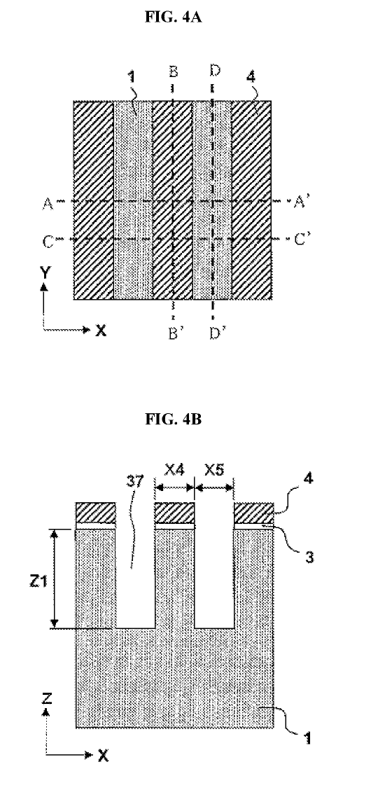

Next, the method of manufacturing the semiconductor device 100 according to the first embodiment of the present invention will be described in detail with reference to FIGS. 4 to 11.

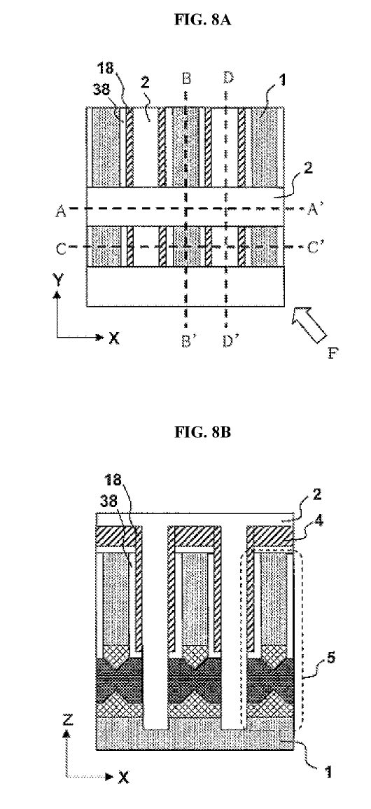

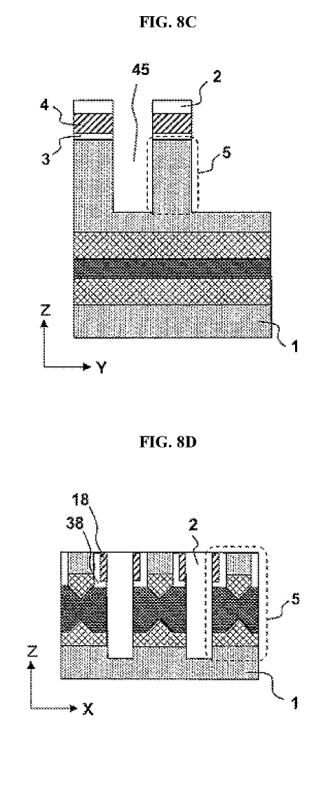

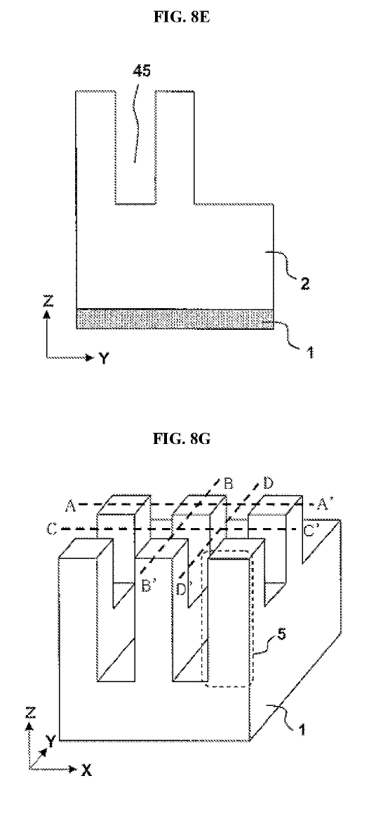

FIGS. 4 to 11 are process drawings illustrating the method of manufacturing the semiconductor device 100 according to the first embodiment, where FIG. A of each drawing is a plan view of the semiconductor device 100 in each manufacturing process, FIG. B is a sectional view at A-A′ in FIG. A, FIG. C is a sectional view at B-B′ in FIG. A, FIG. D is a sectional view at C-C′ in FIG. A, and FIG. E is a sectional view at D-D′ in FIG. A. FIG. 8G is a drawing of FIG. A seen from an F direction.

The sectional view of FIG. B will be mainly used to describe each manufacturing process, and FIGS. A, C, D, E, and G will be used to supplement FIG. B. The methods of manufacturing the semiconductor device 200 according to the second embodiment and the semiconductor device 300 according to the third embodiment are the same as the method of manufacturing the semiconductor device 100 according to the first embodiment, and will not be described separately.

First, as shown in FIG. 4, an insulating film 3 comprising a silicon oxide film was formed on the silicon substrate 1 by CVD, then a mask film 4 comprising a silicon nitride film was formed in the same manner. Next, a photoresist mask (not shown) extending in the Y direction was formed by photolithography so as to cover the location where the silicon pillars 5 would be arranged.

Next, a pattern was transferred to the mask film 4 and the insulating film 3 by anisotropic dry etching using the photoresist mask. This transfer exposed the top surface of the silicon substrate 1 at the bottom of patterned opening.

Next, the exposed silicon substrate 1 was dug down to a depth Z1 of 150 nm by anisotropic dry etching using the mask film 4 as a mask to form a groove 37 extending in the Y direction. At this time, the width X4 in the X direction of the remaining silicon substrate 1 was 50 nm, and the width X5 of the groove 37 was the same. The side surfaces of the groove 37 comprised the silicon substrate 1, the mask film 4, and the insulating film 3, and the silicon substrate 1 was newly exposed at the bottom of the groove.

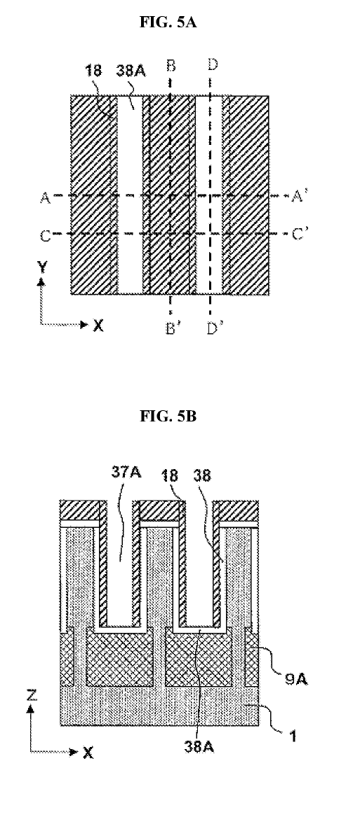

Next, as shown in FIG. 5, an insulating film 38 comprising a silicon oxide film having a thickness of 5 nm was formed inside the groove 37 by thermal oxidation. After a silicon nitride film was formed by CVD to a thickness of 15 nm, the entire surface was etched to form the sidewall film 18 on a side surface of the groove 37.

Next, a bottom diffusion layer 9A was formed on the bottom of the groove 37 below the remaining insulating film 38A by ion injection. The bottom diffusion layer 9A formed on the bottom of the adjacent groove 37 was formed freestanding, and the bottom diffusion layers 9A were not continuous in the X direction in the silicon substrate 1 which would become a silicon pillar. The groove 37 remained as a new groove 37A. The injected impurity may be arsenic, for example, in the case of an N-type transistor.

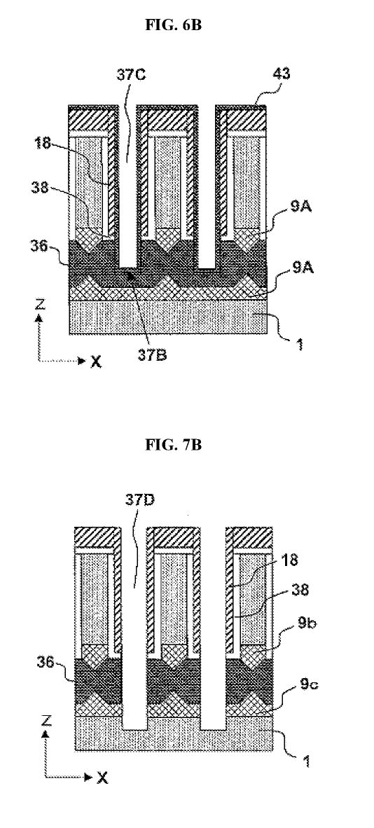

Next, as shown in FIG. 6B, the insulating film 38 (insulating film 38A) exposed on the bottom of the groove 37A and a portion of the silicon substrate 1 below the insulating film 38A were removed by dry etching to form a new groove 37B. The side surfaces of this groove 37B comprised the bottom diffusion layer 9A (silicon substrate 1), the insulating film 38, and the sidewall film 18, and the bottom diffusion layer 9A (silicon substrate 1) was exposed at the bottom of the groove.

Next, a conductive film 43 comprising cobalt (Co) was formed by sputtering so as to cover the inner surface of the groove 37B. This cobalt remained on the inner surface of the groove 37B, and did not diffuse inside the silicon substrate 1 from the surface of the groove 37B.

Next, a silicide layer 36 comprising cobalt silicide (CoSi) was formed by annealing at a treatment temperature of 650° C. to diffuse cobalt inside the silicon substrate 1 where the bottom diffusion layer 9A was formed. Cobalt silicide was formed readily because the cobalt bonded to silicon (Si) by thermal diffusion inside the silicon substrate 1. The bottom diffusion layer 9A was also thermally diffused by this annealing treatment, and therefore was formed integrated continuously with the adjacent bottom diffusion layer 9A, as was likewise the silicide layer 36. The groove 37B now became a new groove 37C covered by the conductive film 43.

Next, as shown in FIG. 7B, the conductive film 43 covering the inner walls of the groove 37C was removed by wet etching using sulfuric acid (H₂SO₄) to expose the silicide layer 36 forming the underlayer of the conductive film 43. Next, the exposed silicide layer 36 (silicide layer 36A) and the bottom diffusion layer 9A formed beneath the silicide layer 36A were removed by dry etching to form a new groove 37D. The silicide layer 36 and the bottom diffusion layer 9A formed integrated in the X direction were now isolated by the groove 37D to form as freestanding for each silicon substrate which would become a silicon pillar.

Described in greater detail, the bottom diffusion layer 9A was isolated by the groove 37D to form the pillar-bottom diffusion layers 9b and 9c, and the silicide layer 36 abutted the bottom surface of the pillar-bottom diffusion layer 9b and the top surface of the pillar-bottom diffusion layer 9c. The side surfaces of the groove 37D comprised the silicon substrate 1, the bottom diffusion layer 9A, the silicide layer 36, the insulating film 38, and the sidewall film 18, and the silicon substrate 1 was exposed at the bottom of the groove.

Next, as shown in FIG. 8, the STI 2 comprising a silicon oxide film was formed by CVD so as to bury the groove 37D and the mask film 4. Next, after the top surface of the STI 2 was flattened by CMP, a groove 45 extending in the X direction was formed by photolithography and dry etching so as to leave the silicon substrate that would become a silicon pillar. The silicon substrate 1 isolated in the X direction by the groove 37D at this time would be divided in the Y direction by a groove 45 to become the silicon pillars 5.

Therefore, referring to FIG. 8G, which shows a projection of only the silicon substrate 1 from the diagonal F direction shown in FIG. 8A, the silicon pillars 5 are convex shapes which remained when depressions were formed in the silicon substrate 1 by dry etching, and were erected on the top surface of the silicon substrate 1. The side surfaces of the groove 45 comprised the silicon pillar 5, the insulating film 38, the sidewall film 18, the STI 2, the insulating film 3, and the mask film 4, and the silicon substrate 1, the insulating film 38, the sidewall film 18, the STI 2, the insulating film 3, and the mask film 4 were exposed at the bottom of the groove.

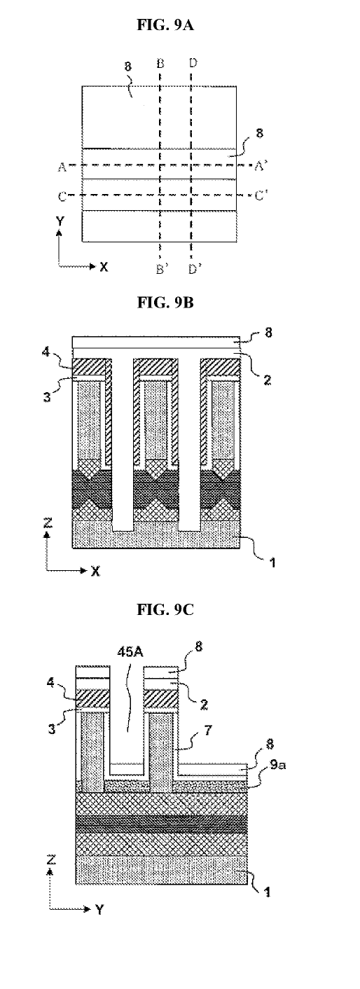

Next, as shown in FIG. 9, the silicon pillars 5 constituted by the groove 45 and the silicon substrate 1 were covered by thermal oxidation by an insulating film 7 comprising a silicon oxide film and having a thickness of 5 nm. Next, an impurity was injected in the bottom of the groove 45 by ion injection to form the pillar-bottom diffusion layer 9a. The pillar-bottom diffusion layer 9a was formed on the silicon substrate 1 above the pillar-bottom diffusion layer 9b, and was electrically connected to the pillar-bottom diffusion layer 9b.

Next, the insulating film 8 comprising a silicon oxide film having a thickness of 20 nm was formed by CVD so as to cover the inner wall of the groove 45. Because the insulating film 8 was formed at this time by a high density plasma (HDP) method having poor coverage property, no film was formed on the side surfaces of the groove 45, and the insulating film 8 covered the insulating film 7 on the bottom of the groove 45 and the STI 2 above the silicon pillars 5. The conditions of HDP were, for example, monosilane (SiH₄), oxygen (O₂), and hydrogen (H₂) as the raw material gases, flow rates of 35 sccm (standard cubic centimeters per minute) (SiH₄), 75 sccm (O₂), and 500 sccm (H₂), a heating temperature of 750° C., a top frequency power of 7500 W, and a bottom frequency power of 4000 W. The groove 45 now because a new groove 45A having the insulating film 8 covering the bottom, and side surfaces comprising the insulating film 7, the insulating film 3, the mask film 4, the STI 2, and the insulating film 8.

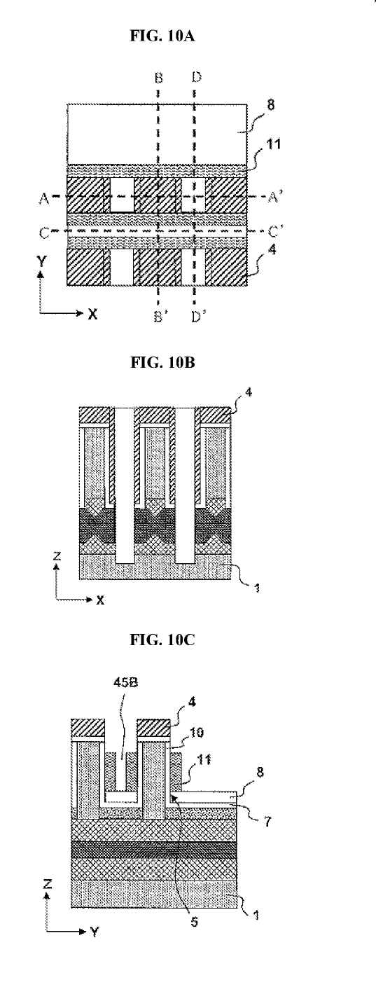

Next, as shown in FIG. 10, the insulating film 7 exposed at a side surface of the groove 45A was removed by wet etching to expose the silicon pillar 5 that would become a channel region. Although the insulating film 8 was removed at this time, the insulating film 8 was sufficiently thicker than the insulating film 7 to leave a thickness of 15 nm. Next, the gate insulating film 10 comprising a silicon oxide film was formed on the exposed silicon pillar 5 by thermal oxidation. The insulating film 7 remaining beneath the insulating film 8 at this time was integrated with the gate insulating film 10.

Next, a polysilicon film (polycrystalline silicon film) having a thickness of 20 nm, which would become a gate electrode, was formed by CVD over the entire surface of the silicon substrate 1. The polysilicon film did not bury the groove 45A at this time, which produced a gap with the polysilicon film standing over the side surface of the silicon pillar 5 in the Y direction.

Next, the polysilicon film on the top surface of the mask film 4 was etched by dry etching to form the gate electrode 11 comprising a polysilicon film on a side surface of the silicon pillar 5 in the Y direction. The insulating film 8 protected the silicon substrate 1 to prevent crystal defects during this etching. The groove 45A became a new groove 45B.

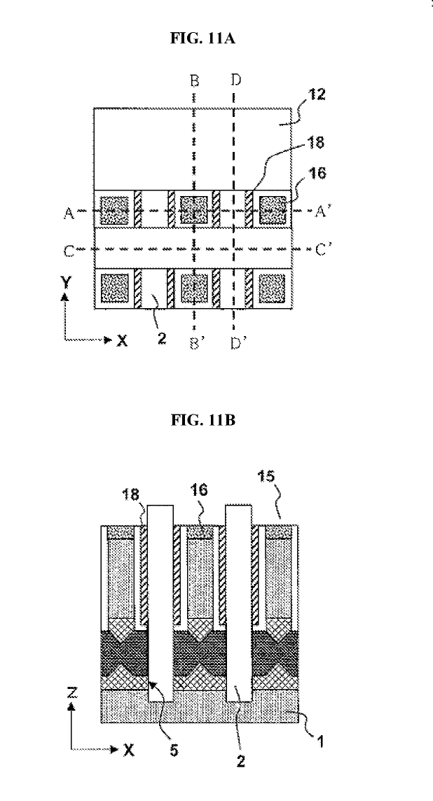

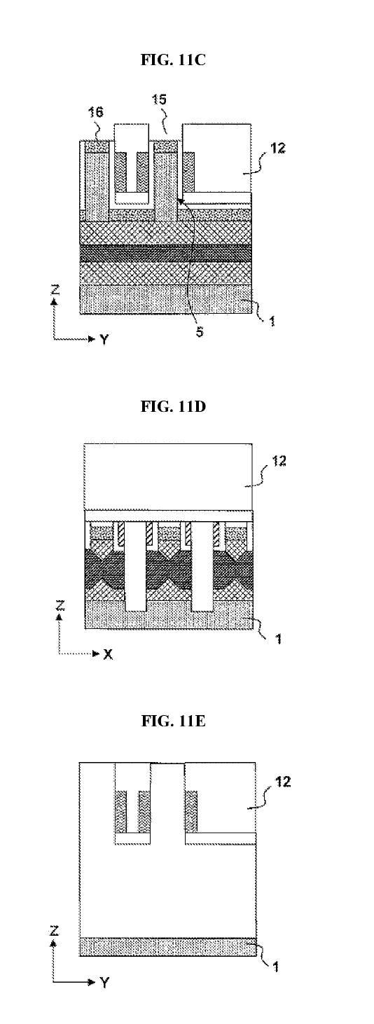

Next, as shown in FIG. 11, the first interlayer insulating film 12 comprising a silicon oxide film was formed by CVD so as to cover the mask film 4 and bury the groove 45B. Next, the first interlayer insulating film 12 was flattened by CMP so as to expose the mask film 4, leaving the first interlayer insulating film 12 only inside the groove 45B.

Next, the mask film 4 comprising a silicon nitride film was removed by wet etching. The sidewall film 18 comprising the underlayer of the mask film 4, being a silicon nitride film, would also have been removed at this time, but was left by restricting the wet etching treatment time. Thus, an opening 15 was formed above the silicon pillar 5 comprising the member underneath the mask film 4. The top surface of the silicon pillar 5 was exposed at the bottom surface of the opening 15, and a portion of the first interlayer insulating film 12 and the STI 2 were exposed at a side surface.

Next, impurity ions (such as phosphorus or arsenic in the case of an N-type transistor) were injected in a top section of the silicon pillar 5 from the opening 15 to form the pillar-bottom diffusion layer 16.

Next, as shown in FIG. 1, the silicon plug 19 was grown on the top surface of the silicon pillar 5 using selective epitaxial growth so as to close the opening 15. Subsequently, in the case of an N-type transistor, ions such as arsenic were injected to form an N-type conductor inside the silicon plug 19, which was electrically connected to the pillar-top diffusion layer 16 formed in a top section of the silicon pillar 5. Next, the second interlayer insulating film 20 comprising a silicon oxide film was formed by CVD so as to cover the silicon plug 19.

Next, the contact holes 27 and 28 were formed by photolithography and dry etching. The contact hole 27 was formed on one side surface of the silicon pillar 5A in the Y direction where the silicon pillar 5B was not arranged, and the silicide layer 36 was exposed at the bottom of the contact hole 27.

The contact hole 28 was formed on the top surface of the silicon plug 19, and at least a portion of the silicon plug 19 was exposed at the bottom of the contact hole 28. The contact holes 27 and 28 may be formed simultaneously or separately.

Next, a metal film comprising tungsten (W), titanium nitride (TiN), and titanium (Ti) was formed by CVD so as to cover the second interlayer insulating film 20 and bury the inside of the contact holes 27 and 28.

Next, the metal film remaining on the top surface of the second interlayer insulating film 20 was removed by CMP to form the metal contact plug 30 on the silicon plug 19 and the metal contact plug 31 on the silicide layer 36. Next, the metal wirings 33 and 34 comprising tungsten (W) and tungsten nitride (WN) were formed by sputtering. During this sputtering, the metal contact plug 31 connected to the silicide layer 36 was connected to the metal wiring 34, and the metal contact plug 30 connected to the silicon plug 19 was connected to the element separation region 33.

The manufacturing method described above completed the semiconductor device 100 shown in FIG. 1.

According to the semiconductor device 100 of the first embodiment described earlier, the silicide layer 36 was disposed beneath the pillar-bottom diffusion layer 9a, and the metal contact plug 31 was connected to the silicide layer 36. This configuration reduces the connection resistance between the metal contact plug 31 and the silicide layer 36 to half the connection resistance (between the metal contact plug 31 and the pillar-bottom diffusion layer 9a) of prior art, and thus can prevent deterioration of the characteristics of a vertical transistor and stabilize the operation of the semiconductor device 100.

According to the semiconductor device 200 of the second embodiment, the connection resistance can be halved in the same manner as with the semiconductor device 100. Furthermore, pillar-bottom diffusion layers 9d are arranged freestanding for each gate electrode constituting a double gate, which can improve the control margin of a vertical transistor and stabilize the operation of the semiconductor device 200 more than the semiconductor device 100.

According to the semiconductor device 300 of the third embodiment, the connection area between the metal contact plug 31 and the silicide layer 36 is expanded compared to the semiconductor device 100, which can further reduce the connection resistance.

Thus, the semiconductor device of the present invention has a configuration in which a silicide bit line passing through a semiconductor pillar extends in a direction perpendicular to a word line. Therefore, contact from a top-layer wiring is made by passing crosswise through the semiconductor pillar in plan view to arrange contact over the entire top surface of the silicide bit line arranged in plan view. Therefore, a contact plug connected to the top-layer wiring can contact the silicide bit line directly without interposing a silicon diffusion layer in between. As a result, increased connection resistance can be avoided.

Although preferred embodiments of the present invention have been described, the present invention is not to be taken as limited to these embodiments. Various modifications may be possible without departing from the scope of the present invention, and the scope of the present invention includes all such modifications.

This application claims priority on the basis of Japanese Patent Application No. 2013-043019 filed on Mar. 5, 2013, the disclosure of which is hereby incorporated by reference.

### EXPLANATION OF REFERENCE NUMBERS

1 Silicon substrate
1A Active region
2 STI
5 Silicon pillar
7 Insulating film
8 Insulating film
9 Pillar-bottom diffusion layer
10 Gate insulating film
11 Gate electrode
12 First interlayer insulating film
16 Pillar-top diffusion layer
19 Silicon plug
20 Second interlayer insulating film
27 Contact hole
31 Metal contact plug
33 Metal wiring
34 Metal wiring
36 Silicide layer
50 Unit transistor
100 Semiconductor device
200 Semiconductor device
300 Semiconductor device

1. A semiconductor device comprising:
an element-isolation region formed on a semiconductor substrate;
an active region surrounded by the element-isolation region;
a semiconductor pillar disposed in the active region so as to protrude from the surface of the semiconductor substrate;
a gate electrode disposed on a side surface of the semiconductor pillar, with a gate insulating film interposed in between, so as to extend in a first direction;
a pillar-top diffusion layer disposed on a top-end section of the semiconductor pillar;
a pillar-bottom diffusion layer disposed on a bottom-end section of the semiconductor pillar;
a channel section disposed between the pillar-top diffusion layer and the pillar-bottom diffusion layer;
a silicide layer disposed beneath the pillar-bottom diffusion layer so as to extend in a second direction perpendicular to the first direction;
a contact plug disposed so as to contact the silicide layer at a bottom-end section; and
a top-layer wiring disposed so as to contact the contact plug at a top-end section;
wherein the contact plug passes through the pillar-bottom diffusion layer to connect to the silicide layer.

2. The semiconductor device according to claim 1, wherein:
the contact plug is connected directly to the silicide layer without interposing the pillar-bottom diffusion layer in between;
the silicide layer has a lower resistance value than the pillar-bottom diffusion layer; and
power is supplied through the silicide layer having a lower resistance than the pillar-bottom diffusion layer.

3. The semiconductor device according to claim 1, wherein the silicide layer functions as a power supply wiring to the pillar-bottom diffusion layer.

4. The semiconductor device according to claim 1, wherein the pillar-top diffusion layer constitutes one of a source or a drain, and the pillar-bottom diffusion layer constitutes the other of a source or a drain.

5. The semiconductor device according to claim 1, wherein the width of the first direction of the contact plug is less than or equal to the width of the first direction of the semiconductor pillar provided with the contact plug.

6. The semiconductor device according to claim 1, wherein the element-isolation region is disposed in a deeper location than the pillar-bottom diffusion layer.

7. The semiconductor device according to claim 1, wherein the silicide layers is arranged integrated in the first direction.

8. A semiconductor device according to claim 1, wherein two of the silicide layers are arranged in the first direction.

9. The semiconductor device according to claim 8, wherein the width of the first direction of the semiconductor pillar is greater than the width of the first direction of the semiconductor pillar provided with the contact plug.

10. The semiconductor device according to claim 1, wherein the bottom of the contact plug is arranged in the first direction so as to contact the top surface and at least a section of a side surface of the silicide layer.

11. The semiconductor device according to claim 10, wherein the width of the first direction of the contact plug is greater than the width of the first direction of the semiconductor pillar provided with the contact plug.

12. The semiconductor device of claim 1, wherein:
the silicide layer constitutes a silicide bit line passing through the semiconductor pillar; and
the contact plug is connected directly to the silicide bit line without interposing the pillar-bottom diffusion layer in between.

13. A method of manufacturing a semiconductor device, comprising:
forming an element-isolation region on a semiconductor substrate;
forming an active region surrounded by the element-isolation region;
forming a pillar-shaped semiconductor pillar in the active region so as to protrude from the surface of the semiconductor substrate;
forming a gate electrode on a side surface of the semiconductor pillar, with a gate insulating film interposed in between, so as to extend in a first direction;
forming a pillar-top diffusion layer on a top-end section of the semiconductor pillar;
forming a pillar-bottom diffusion layer on a bottom-end section of the semiconductor pillar;
forming a channel section between the pillar-top diffusion layer and the pillar-bottom diffusion layer;
forming a silicide layer beneath the pillar-bottom diffusion layer so as to extend in a second direction perpendicular to the first direction;
forming a contact plug so as to contact the silicide layer at a bottom-end section;
forming a top-layer wiring so as to contact the contact plug at a top-end section; and
passing the contact plug through the pillar-bottom diffusion layer to connect to the silicide layer.

14. The method of manufacturing a semiconductor device according to claim 13, wherein:
the semiconductor substrate is a silicon substrate; and
cobalt is diffused by annealing into the silicon substrate formed with the pillar-bottom diffusion layer to form a cobalt silicide layer as the silicide layer.

15. The method of manufacturing a semiconductor device according to claim 13, wherein:
the contact plug is connected directly to the silicide bit line without interposing the pillar-bottom diffusion layer in between;
the silicide layer has a lower resistance value than the pillar-bottom diffusion layer; and
power is supplied through the silicide layer having a lower resistance than the pillar-bottom diffusion layer.

16. The method of manufacturing a semiconductor device according to claim 15, wherein the silicide layer functions as a power supply wiring to the pillar-bottom diffusion layer.

17. The method of manufacturing a semiconductor device according to claim 13, wherein the pillar-top diffusion layer constitutes one of a source or a drain, and the pillar-bottom diffusion layer constitutes the other of a source or a drain.
